(19) United States
(12) Patent Application Publication
(10) Pub. No.: US 2006/0145756 A1
(43) Pub. Date: Jul. 6, 2006

(54) Apparatus and method for processing description information of multimedia data

(75) Inventors: Jin Soo Lee, Seoul (KR); Kyoung Ro Yoon, Seoul (KR); Jung Min Song, Seoul (KR)

Correspondence Address: SIDLEY AUSTIN BROWN & WOOD LLP, 555 CALIFORNIA STREET, SUITE 2000, SAN FRANCISCO, CA, 94104-1715, US

(73) Assignee: LG Electronics, Inc.

(21) Appl. No.: 11/365,208

(22) Filed: Mar. 1, 2006

Related U.S. Application Data
(62) Division of application No. 09/902,664, filed on Jul. 12, 2001.

(30) Foreign Application Priority Data
Jul. 14, 2000 (KR) 40591/2000

(51) Int. Cl. H03F 3/38

(52) U.S. Cl. 330/10

(57) ABSTRACT

In an apparatus and a method for processing description information of multimedia data, in order to reflect a user's preference about multimedia data, a usage history of a user is made by adding description information to the multimedia data, in order to manage the usage history efficiently the apparatus includes, a server adding description information to the multimedia, and a terminal transmitting/receiving multimedia data to/from the server, storing a user's usage history about the multimedia data, grasping a preference of a user with the stored usage history and providing the preference of the user to the server, accordingly multimedia sequences can be efficiently managed with the usage history of the user, a restrictive memory unit can be efficiently used, and grouping of lots of multimedia data can be easily performed by displaying all commonly applicable data as the same result by using common information or application group information without retrieving characteristic information.

### CROSS REFERENCE TO RELATED APPLICATION

The present application is a divisional of co-pending application Ser. No. 09/902,664, filed Jul. 12, 2001, the entirety of which is incorporated by reference herein.

### BACKGROUND OF THE INVENTION

1. Field of the Invention

The present invention relates to an apparatus and a method for processing description information of multimedia data reflecting a user's preference, and in particular to an apparatus and a method for processing description information of multimedia data which is capable of reflecting efficiently a user's preference about multimedia by making a usage history of a user by adding description information to multimedia data and managing the usage history of the user efficiently.

2. Description of the Prior Art

Recently, according to increase of multimedia related services such as a digital broadcast, multimedia service providers have tried to provide more improved user adaptive services. In a method disclosed in U.S. Pat. No. 5,861,884, a help is provided to each of users by making a usage history about frequent used service items of each user and a user interface applicable to each user is provided by using the usage history. In more detail, by describing the help as a tree format, levels of articles can be changed according to the number of request times by the user (i.e., a certain articles placed at lower levels can be placed at higher levels when the user uses the certain article frequently), accordingly a retrieval path for retrieving a user request item can be shorten.

In addition, in a method disclosed in U.S. Pat. No. 5,835,088, functions of multimedia buttons can be set as short-cut keys according to a user's request, accordingly a more efficient user applicable interface can be provided.

In order to obtain a user applicable multimedia service, a method for reflecting a user's preference through user history information is used. In more detail, a method for retrieving and displaying multimedia by reflecting a user's preference is used.

In a method disclosed in U.S. Pat. No. 5,416,693, a display operation preference (for example, replay, fast forward, etc.) of a user is stored in a history storing unit, multimedia data is segmented, a user's preference by the segments on the basis of the display operation preference is stored in the history storing unit as a point format. More intelligent display methods are disclosed in U.S. Pat. Nos. 5,861,884 and 5,835,088. In more detail, a segment replayed many times is defined as a more important segment, in performing of a multimedia search function, the segment replayed many times is displayed more slowly than a normal display speed.

In a method disclosed in WIPO No. 9,747,135, a user's preference channel and user's preference device information (for example, a volume) of each channel are stored in the history storing unit, a user applicable circumstances is provided on the basis of the stored information.

In a method disclosed in U.S. Pat. No. 5,758,259, when a program guide is provided to a user, the program guide having lots of quantity is not transmitted as it is, but general subscription information of a user is stored, and the program guide by each user is provided on the basis of the stored subscription information concentrated on a preferred genre of each user.

In a method disclosed in U.S. Pat. No. 5,734,444, a user preference program is automatically selected and recorded on the basis of a multimedia subscription history of a user. A user applicable service using the above-mentioned method has been commercially provided in a Tivo/Replay TV in U.S. and has been regarded as a very important field.

Accordingly, in the above-mentioned conventional method, as a method reflecting the latest preference information of a user, user's history information can be used efficiently in a field providing preference information of a user having a certain condition.

Recently, a smart card concept has been introduced in order to provide not a service focused on a server or a device but a service focused on a user.

In more detail, in a method disclosed in U.S. Pat. No. 5,814,798, a user applicable service is consistently provided to a user by recording user's preference information on the smart card.

The above-mentioned service methods according to the prior art are mainly used in video services such as a VOD (Video On Demand), a Pay per View, but recently the biggest application field of the conventional service methods is a broadcast field as a digital broadcast is activated. In more detail, a user preference program can be automatically stored or a program guide can be made on the basis of user preference programs and user preference time. However, contrary to general video services, in broadcast data of a broadcast field, most of programs are the same programs having different content.

For example, a serial drama has common characteristics such as the same actor and the same director or a news program has common characteristics such as the same anchor and the same reporting field. Excluding parts directly related to contents of the programs, the above-mentioned programs have common characteristics (i.e., the same director in the serial drama or the same anchor in the news program) even they are televised at different time.

When a certain information is described every time in a usage history of a user without considering common characteristics, it is a waste of storing space, a processing process of a certain information is increased, information of a broadcast program can not be used efficiently, accordingly a storing space and a processing time are used wastefully.

### SUMMARY OF THE INVENTION

It is an object of the present invention to provide an apparatus and a method for processing description information of multimedia data which is capable of using a memory apparatus efficiently by managing multimedia data with a user's history.

It is another object of the present invention to provide an apparatus and a method for processing description information of multimedia data which is capable of easily grouping a plurality of multimedia data without searching characteristic information content by displaying commonly applicable data as the same result by using common information or application group information 900.

In order to achieve the above-mentioned objects, there is provided an apparatus for processing description information of multimedia data including a server 100 adding description information to multimedia, and a terminal 200 transmitting/receiving multimedia data to/from the server 100, storing a user's usage history about the multimedia data, grasping a preference of a user with the stored usage history and providing the preference of the user to the server 100.

In order to achieve the above-mentioned object, there is provided a method for processing description information of multimedia data in accordance with a first embodiment of the present invention including classifying description information into common characteristic information 300 commonly applicable to multimedia data and inherent characteristic information 400 inherently applicable to the multimedia data when the multimedia data is transmitted from a server to a terminal, constructing a hierarchical information description format by adding each characteristic information of the multimedia data to a subordinate of the common characteristic information 300 and the inherent characteristic information 400, respectively, and adding the hierarchical information description format to the multimedia data.

In order to achieve the above-mentioned object, there is provided a method for processing description information of multimedia data in accordance with a second embodiment of the present invention including comparing a program ID (Identification) 500 of displayed multimedia data with a program ID stored in a memory unit when the multimedia data is displayed on a terminal, storing an inherent list in the memory unit when the program ID 500 is the same as the program ID stored in the memory unit, and storing a common list and the inherent list in the memory unit when the program ID 500 is not the same as the program ID stored in the memory unit.

In order to achieve the above-mentioned object, there is provided a method for processing description information of multimedia data in accordance with a third embodiment of the present invention including comparing a program ID 500 of displayed multimedia data with a program ID stored in an additional memory unit when the multimedia data is displayed on a terminal, storing an inherent list in a memory unit when the program ID 500 is the same as the stored program ID, and storing the inherent list in the memory unit and the common list in the additional memory unit when the program ID 500 is not the same as the stored program ID.

### BRIEF DESCRIPTION OF THE DRAWINGS

FIG. 1 is a block diagram illustrating a processing system of multimedia data reflecting a user's preference in accordance with the present invention;

FIG. 2 is a block diagram illustrating a first embodiment of description information added to multimedia data in accordance with the present invention;

FIG. 3 illustrates a usage history of a user with list items in accordance with a first embodiment of the present invention;

FIG. 4 is a block diagram illustrating description information added to multimedia data in accordance with a second embodiment of the present invention;

FIG. 5 is a block diagram illustrating description information added to multimedia data in accordance with a third embodiment of the present invention;

FIG. 6 is a block diagram illustrating description information added to multimedia data in accordance with a fourth embodiment of the present invention;

FIG. 7 illustrates a usage history of a user with list items in accordance with a second embodiment of the present invention;

FIG. 8 illustrates a usage history of a user with list items in accordance with a third embodiment of the present invention; and

FIG. 9 illustrates a usage history of a user with list items in accordance with a fourth embodiment of the present invention.

### DETAILED DESCRIPTION OF THE PREFERRED EMBODIMENT

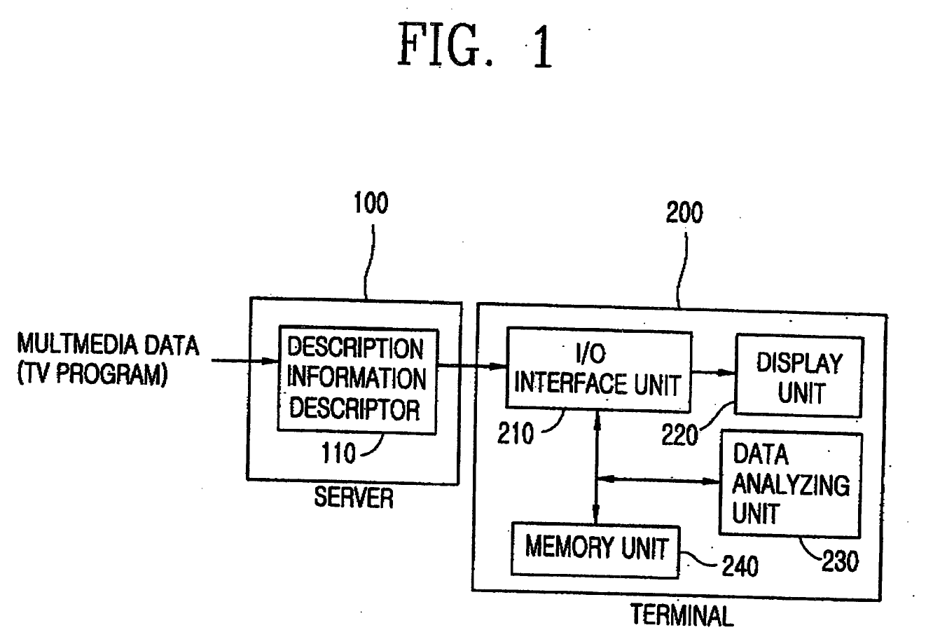

FIG. 1 is a block diagram illustrating a processing system of multimedia data reflecting a user's preference in accordance with the present invention. As depicted in FIG. 1, a multimedia data processing system reflecting a user's preference includes a server 100 providing multimedia data to a user, a description information descriptor 110 of the server 100 adding description information to the multimedia data in order to extract user preference information of the multimedia data, a terminal 200 receiving the multimedia data and displaying the received multimedia data to a user, an I/O (input/output) interface unit 210 of the terminal 200 receiving the multimedia data and transmitting the user preference information to the server 100, a data analyzing unit 230 analyzing the description information added in the description information descriptor 110, and a memory unit 240 storing description information according to the analysis result.

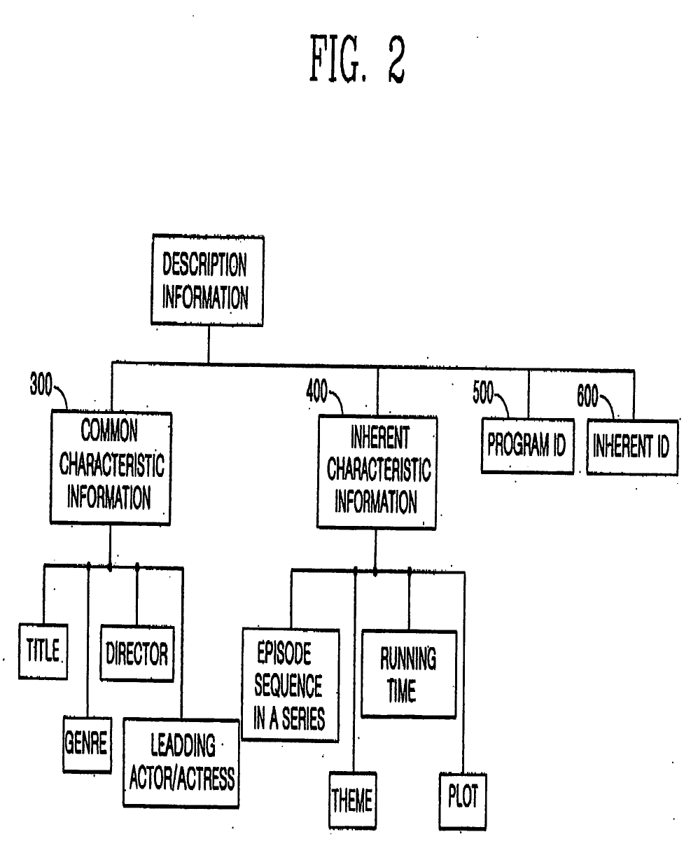

FIG. 2 is a block diagram illustrating a first embodiment of description information added to multimedia data in accordance with the present invention. As depicted in FIG. 2, description information added to serially televised multimedia data (program) such as a serial drama includes common characteristic information 300 about a director, a leading actor (actress), a title, a genre, etc., inherent characteristic information 400 about an episode sequence of a program, a running time of a program, a theme, a plot, etc. of the multimedia data (program), a program ID (Identification) 500 for judging whether the multimedia data (program) is the same program (for example, one episode of serial drama) having the common characteristic information 300, and an-inherent ID (identification) for classifying multimedia data.

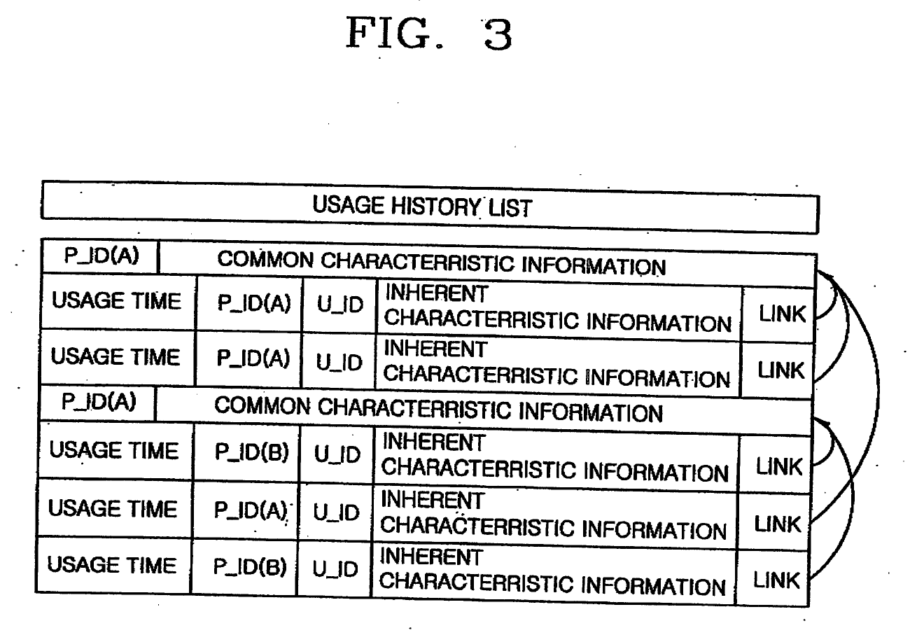

FIG. 3 illustrates a usage history of a user with list items in accordance with a first embodiment of the present invention. As depicted in FIG. 3, a list constructed with the program ID 500 and the common characteristic information 300 is defined as a common list, a list constructed with a usage time, the program ID 500, the inherent ID 600 and the inherent characteristic information 400 is defined as an inherent list, the inherent list is linked to the common list.

An apparatus and a method for processing description information of multimedia data in accordance with the present invention will now be described with reference to accompanying FIGS. 1, 2 and 3.

In processing of multimedia data of an eight-part series, the description information descriptor 110 of the server 100 classifies the common characteristic information 300 into a title, a director, a genre, a leading actor/actress, etc. and classifies the inherent characteristic information into an, episode sequence, a running time of a program, a theme, a plot, etc. In addition, the program ID 500 of the multimedia data is defined, the inherent ID 600 is defined in order to classify the multimedia data.

After that, when a user selects ‘the first episode of a series’, the description information descriptor 110 adds the common characteristic information 300, the inherent characteristic information 400 and the inherent ID 600 to the multimedia data (‘the first episode of the series’) and transmits it to each terminal 200. And, the user watches ‘the first episode of the series’ transmitted from the I/O interface unit 210 through the display unit 220.

Herein, the data analyzing unit 230 classifies the multimedia data (‘the first episode of the series’) into the inherent characteristic information 400, the common characteristic information 300, the program ID 500 and the inherent ID 600, and the memory unit 240 stores the multimedia data as list items as depicted in FIG. 3.

In more detail, the program ID 500 is stored in P_ID, contents such as a title, a director, a genre, a main actor/actress, etc. of the common characteristic information 300 are stored in a common characteristic information item, contents such as the episode sequence, the running time of a program, a theme, a plot, etc. of the inherent characteristic information are stored in an inherent characteristic information item. In addition, the inherent ID 600 is stored in U_ID, a usage time of the user is stored in a usage time item.

After that, when a user selects ‘the second episode of the series’, the description information descriptor 110 adds common characteristic information 300, an inherent characteristic information 400, a program ID 500, an inherent ID 600 to ‘the second episode of the series’ and transmits it. Then, the user watches ‘the second episode of the series’ transmitted through the I/O interface unit 210 on the display unit 220.

Herein, a program ID 500 of ‘the second episode of the series is compared with the program ID 500 stored in the memory unit 240. The program ID 500 of ‘the second episode of the series’ already exists in the memory unit 240 (because, it is another episode of the same series as the ‘first episode of the series’), an inherent list of ‘the second episode of the series’ is stored in the memory unit 240 and is linked to the common list.

In addition, when the user selects ‘the first episode of another series’, a program ID 500 of ‘the first episode of another series’ is compared with the program ID 500 stored in the memory unit 240. Herein, the program ID 500 of ‘the first episode of another series’ does not exist in the memory unit 240, a common list of ‘the first episode of another series’ is stored in the memory unit 240. After that, an inherent list of ‘the first episode of another series’ is stored in the memory unit 240 and is linked to the common list.

After that, when the user selects ‘the third episode of the series’, a program ID 500 of ‘the third episode of the series’ already exists in the memory unit 240, an inherent list of ‘the third episode of the series’ is stored in the memory unit 240 and is linked to the common list of ‘the first episode of the series’.

On the basis of above-mentioned embodiments, the description information descriptor 110 is defined as below description information added to the multimedia data and transmitted to the terminal 200.

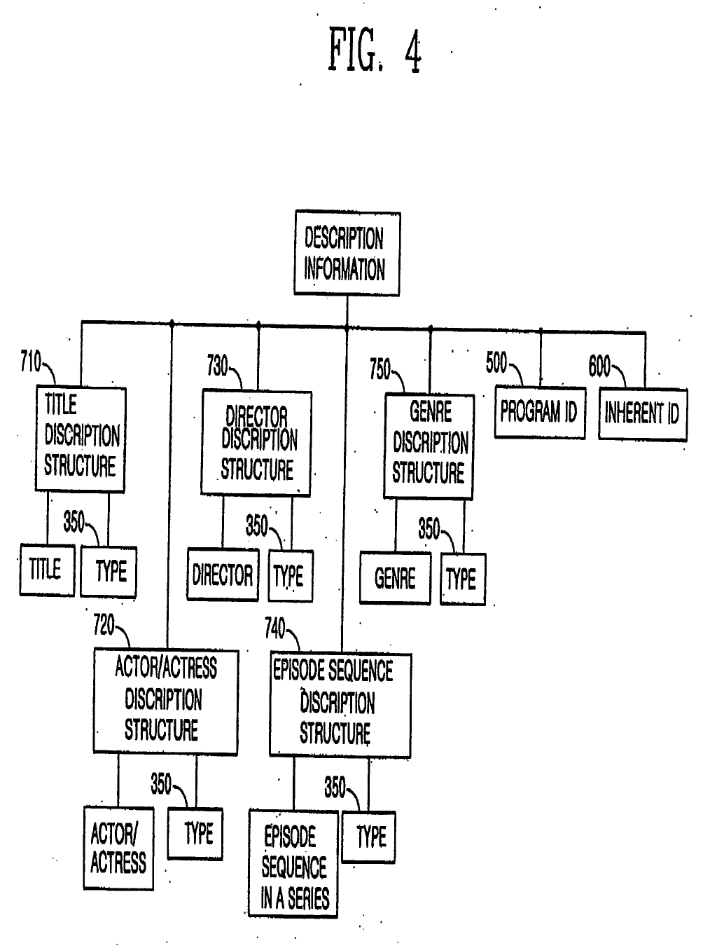

FIG. 4 is a block diagram illustrating description information added to multimedia data in accordance with a second embodiment of the present invention. As depicted in FIG. 4, the description information description unit 110 defines multimedia data as a title description structure 710, a director description structure 730, an actor description structure 720, an episode sequence structure 740 and a genre description structure 750, a program ID 500 for distinguishing whether the multimedia data is the same program, and an inherent ID 600. The title description structure 710 is hierarchically subdivided into title information and type information 350. The director description structure 730 is hierarchically subdivided into director information and type information 350. The genre description structure 750 is subdivided into genre information and type information 350.

Each type information 350 classifies each characteristic information (title, director, genre) into common characteristic information 300 and inherent characteristic information 400.

Then the classified characteristic information is stored in the memory unit 240 in order to avoid duplication.

In other words, when a user subscripts a program, the data analyzing unit 230 compares a program ID 500 of a present subscription program with pre-stored program IDs 500, when the program ID 500 of the present subscription program is already stored in the memory unit 240, only the inherent list of the present subscription program is stored in the memory unit 240, when the program ID 500 of the present subscription program is not stored in the memory unit 240, the inherent list and the common list are stored in the memory unit 240.

Accordingly, by managing the memory unit 240 with the above-mentioned method, it is possible to avoid duplication in storing of the common characteristic information.

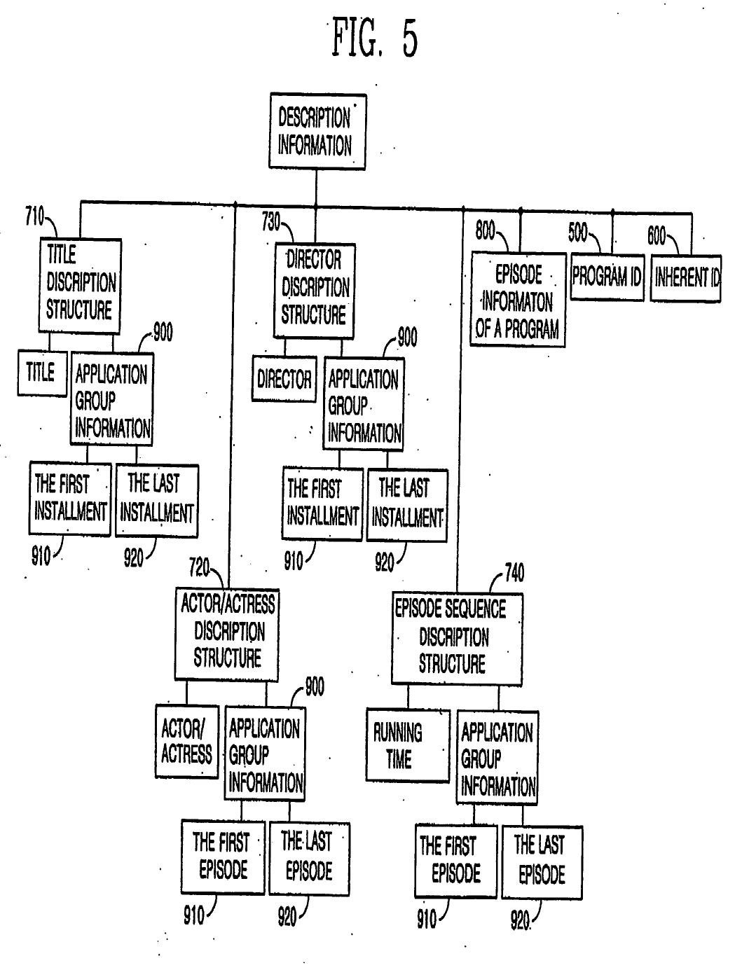

FIG. 5 is a third embodiment of description information added to multimedia data in accordance with the present invention. As depicted in FIG. 5, the description information descriptor 110 classifies description information into an inherent ID 600 for differentiating multimedia data from other multimedia data, a program ID 500 for indicating the multimedia data is one of a series, episode information for indicating the episode sequence of the multimedia data, a title description structure 710, a director description structure 730, an actor/actress description structure 720 and an episode sequence description structure 740. The title description structure 710 is subdivided into title information and application group information 900, the director description structure 730 is subdivided into director information and application group information 900, the actor/actress description structure 720 is subdivided into actor information and application group information 900, and the episode sequence description structure 740 is subdivided into the episode sequence information and application group information 900. Each application group information 900 is subdivided into the first episode 910 and the last episode 920.

The episode information is for indicating the episode sequence of the multimedia, and the application group information 900 indicates whether each characteristic information is adapted to the whole episodes of multimedia data or some episodes of the multimedia data. In more detail, the application group information is subdivided into the first episode 910 and the last episode 920. For example, in the director description format 900, when the first episode 910 is ‘1’ and the last episode is ‘8’, it means the same director from the first episode to the eighth episode in an eighth-part series. Herein, a present subscription episode is described as the last episode 920, when the last episode is determined, the determined last episode 920 is described.

In more detail, when a user subscripts ‘the third episode of a series’, the description information descriptor 110 transmits multimedia data having an inherent ID 600, a program ID 500, ‘3’ as episode information, a director of a director description structure 730, ‘1’ as the start episode information 910 and ‘3’ as the last episode information 920. Herein, the last episode information 920 can be designated in advance, when the eighth episode is the last episode 920, ‘8’ is designated as the last episode information 920.

In the description information added to multimedia data in accordance with the third embodiment of the present invention, information for indicating each characteristic information is applicable to only a pertinent episode or all episodes is further included.

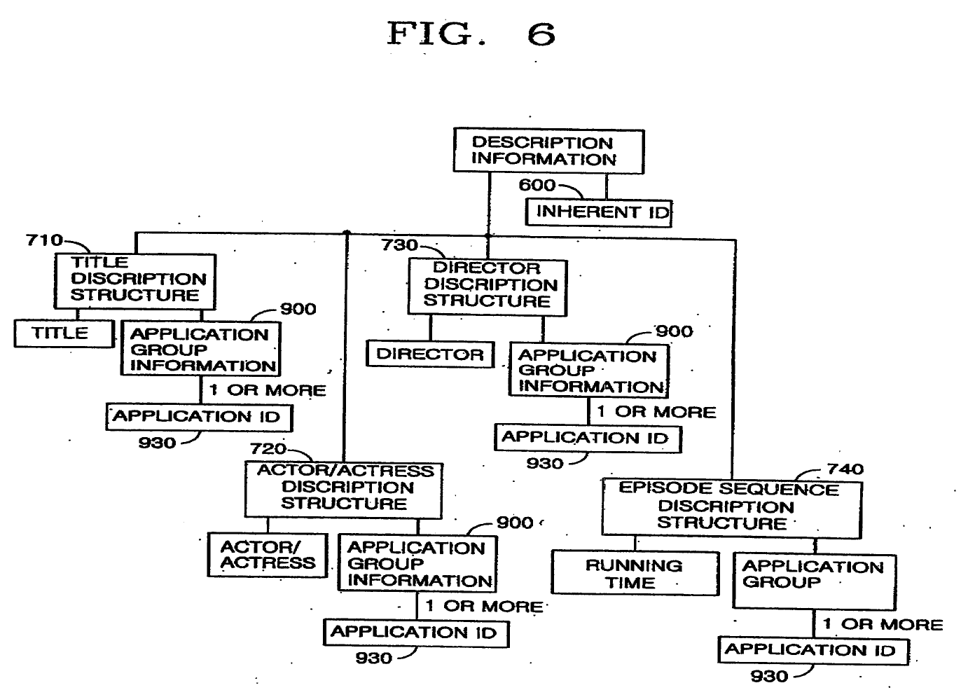

FIG. 6 is a block diagram illustrating description information added to multimedia data in accordance with a fourth embodiment of the present invention. As depicted in FIG. 6, when the multimedia data is not a series, the description information descriptor 110 classifies description information into an inherent ID 600 for differentiating multimedia data from other multimedia data, a title description structure 710, a director description structure 730, an actor/actress description structure 720 and an episode sequence description structure 740. The title description structure 710 is subdivided into title information and application group information 900, the director description structure 730 is subdivided into director information and application group information 900, the actor/actress description structure 720 is subdivided into actor information and application group information 900, and the episode sequence description structure 740 is subdivided into the episode sequence information and application group information 900. Each application group information 900 has not less than one application ID as a subordinate item.

Each application group information 900 has the application ID 930 in order to check whether each characteristic information is applicable to only the pertinent multimedia data or also other multimedia data.

The above-mentioned description information added to multimedia data in accordance with the fourth embodiment of the present invention can be efficiently used for not a series but multimedia data having lots of common characteristic information such as a news program. There can be not less than one application ID 930 of the application group information 900. Information about programs, in which the common characteristic information 300 is applicable, is displayed through the application ID 930 of the multimedia data.

A method for managing a user history by storing multimedia data from the description information descriptor 110 in the memory unit 240 will now be described.

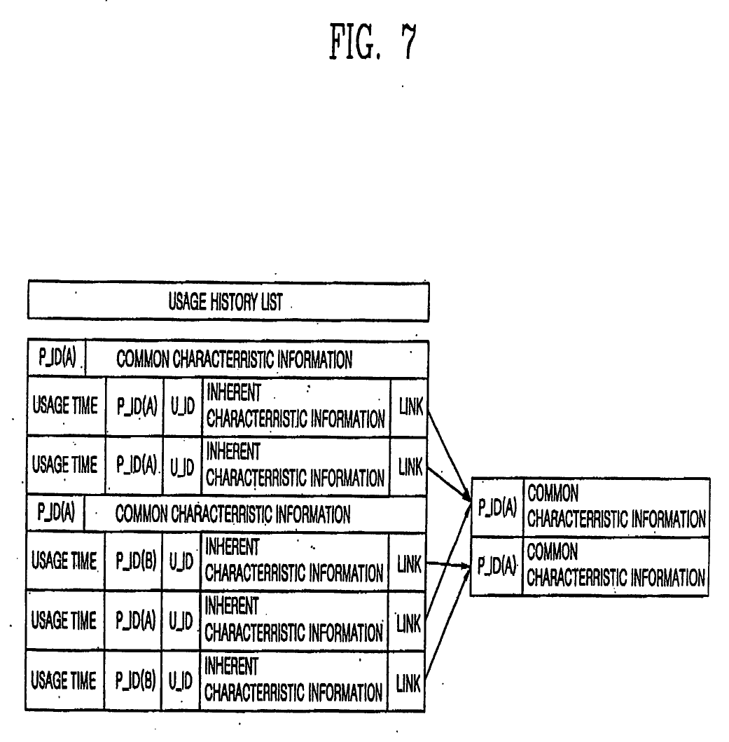

FIG. 7 illustrates a usage history of a user with list items in accordance with a second embodiment of the present invention. As depicted in FIG. 7, the memory unit 240 links an inherent list to a common list of another memory unit storing the common characteristic information 300.

Only inherent characteristic information 400 is stored in each item of the inherent list, the common characteristic information is stored and managed in not a usage history list but another memory unit. In more detail, only inherent characteristic information 400 of a pertinent item is described in each item of the inherent list, the common characteristic information 300 is stored in an additional memory unit (not shown), each item of the inherent list includes link information for linking to the common characteristic information 300. A smart card can be used as the additional memory unit.

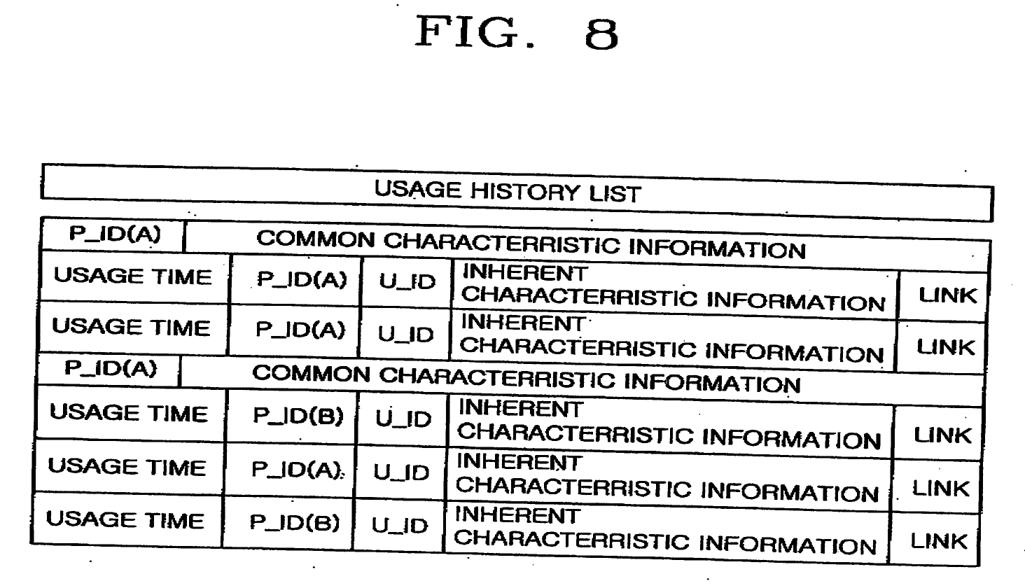

FIG. 8 illustrates a usage history of a user with list items in accordance with a third embodiment of the present invention. As depicted in FIG. 8, in the usage history of the user, a list including a program ID 500, common characteristic information, an inherent ID 600, a usage time and inherent characteristic information by each multimedia data is defined as an inherent list.

The inherent list processes a usage history with only the program ID 500. In more detail, because each multimedia data has a program ID 500 and common characteristic information also has the same program ID 500, although there is no link information in each list, the inherent list and the common list can be connected by connecting both program ID by a mapping or an address reference methods, etc. As described above, the method for connecting the common characteristic information 300 of multimedia data with the program ID 500 can be used when there is the small quantity of data.

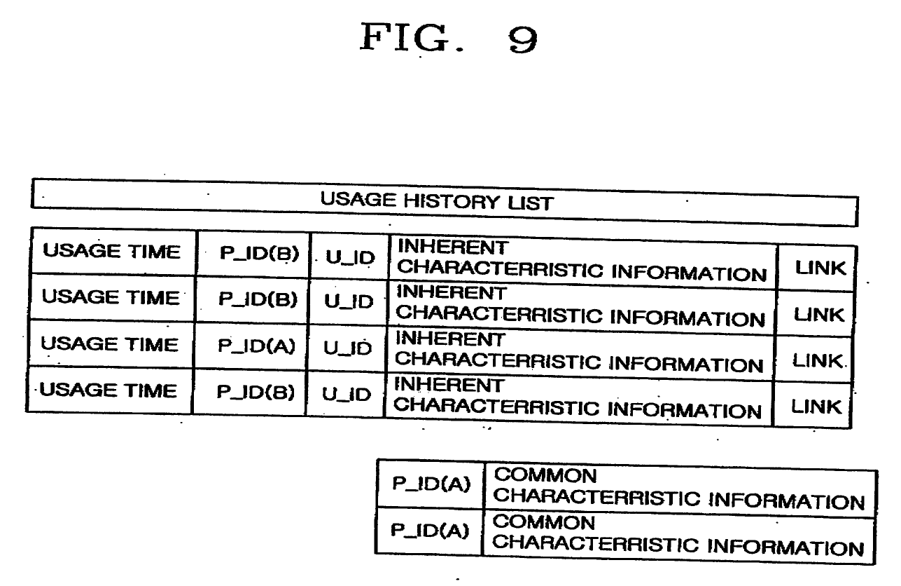

FIG. 9 illustrates a usage history of a user with list items in accordance with a fourth embodiment of the present invention. As depicted in FIG. 4, a list including a usage time, a program ID 500, an inherent ID 600, an inherent characteristic information 400 is defined as an inherent list, a list including a program ID 500, a common characteristic information 300 as a common list, the inherent list and the common list are stored in an additional memory unit (not shown).

Only inherent characteristic information 400 is described in the inherent list, the common characteristic information 300 is an additional memory unit (not shown) only managing the common characteristic information, each item of the inherent list includes link information for linking to the common characteristic information.

As described above, the method for connecting the common characteristic information about the same multimedia data with the program ID 500 can be used when the quantity of data is small.

As above-described embodiments, in a multimedia service reflecting a user preference, multimedia can be efficiently managed with a user's history, accordingly a memory unit can be efficiently used. In particular, in a digital TV circumstances, because most of broadcast data are series, an apparatus and a method for processing description information of multimedia data in accordance with the present invention can be efficiently used for applications reflecting a user preference about programs.

The apparatus and the method for processing description information of multimedia data can easily perform grouping of lots of multimedia data belonging to series programs by displaying commonly applicable data as the same result with common information or application group information without retrieving characteristic information.

What is claimed is:

1. A method for processing description of multimedia content, the method comprising:
receiving a first description describing content in a first multimedia object, the first description including a first identifier and a reference to a group of multimedia objects, wherein the first identifier identifies the first multimedia object and the reference to the group indicates that the first multimedia object belongs to the group of multimedia objects; and
receiving a description about the group of multimedia objects, wherein the description about the group includes a group identifier that identifies the group.

2. The method of claim 1, wherein the reference to the group includes information to determine the group identifier.

3. The method of claim 2, further comprising:
using the group identifier to associate the first multimedia object with the description about the group.

4. The method of claim 1, further comprising:
storing a usage history that lists user actions and associates the first identifier with each user action that is related to the first multimedia object.

5. The method of claim 4, wherein the usage history includes a reference to a multimedia description.

6. The method of claim 5, wherein the referenced multimedia description includes at least a portion of the description about the group.

7. The method of claim 1, further comprising:
using the first description or the description about the group to describe user preferences.

8. The method of claim 1, wherein the group of multimedia objects represents a series of episodes, and wherein the reference to the group indicates that the first multimedia object represents an episode of the series.

9. The method of claim 8, wherein the reference to the group specifies an episode number for the first multimedia object.

10. The method of claim 1, wherein the description about the group includes a title for the group of multimedia objects.

11. The method of claim 1, wherein the description about the group specifies a genre for the group of multimedia objects.

12. The method of claim 1, wherein the description about the group specifies a director or one or more actors or actresses for the group of multimedia objects.

13. The method of claim 1, wherein the first description includes a hierarchical structure in which the reference to the group is represented at the same hierarchical level as a container including content description elements.

14. The method of claim 13, wherein the content description elements include an element describing a title or a genre for the first multimedia object.

15. The method of claim 13, wherein the content description elements include an element specifying a director, an actor, or an actress for the first multimedia object.

16. The method of claim 13, wherein the content description elements include an element for a textual description of the content in the first multimedia object.

17. A method for providing description of multimedia content, the method comprising:
generating a first description describing content in a first multimedia object, the first description including a first identifier and a reference to a group of multimedia objects, wherein the first identifier identifies the first multimedia object and the reference to the group indicates that the first multimedia object belongs to the group of multimedia objects; and
transmitting the first description to a user terminal.

18. The method of claim 17, further comprising:
generating a description about the group of multimedia data objects, wherein the description about the group includes a title for the group of multimedia objects and a group identifier to identify the group of multimedia objects.

19. The method of claim 18, further comprising:
transmitting the description about the group to the user terminal.

20. The method of claim 18, wherein the reference to the group includes information to determine the group identifier.

21. The method of claim 17, wherein the group of multimedia objects represents a series of episodes, and wherein the reference to the group indicates that the first multimedia object is an episode of the series.

22. The method of claim 21, wherein the reference to the group specifies an episode number for the first multimedia object.

23. The method of claim 17, wherein the first description includes a hierarchical structure in which the reference to the group is represented at the same hierarchical level as a container including content description elements.

24. The method of claim 23, wherein the content description elements include an element describing a title or a genre for the first multimedia object.

25. The method of claim 23, wherein the content description elements include an element specifying a director, an actor, or an actress for the first multimedia object.

26. The method of claim 23, wherein the content description elements include an element for a textual description of the content in the first multimedia object.

27. A system for processing description of multimedia content, the system comprising:
a memory unit; and
data processing apparatus configured to:
receive a first description describing content in a first multimedia object, the first description including a first identifier and a reference to a group of multimedia objects, wherein the first identifier identifies the first multimedia object and the reference to the group indicates that the first multimedia object belongs to the group of multimedia objects;
receive a description about the group of multimedia objects, wherein the description about the group includes a group identifier that identifies the group; and
store in the memory unit at least a portion of the first description or the description about the group.

28. The system of claim 27, wherein the reference to the group includes information to determine the group identifier, and wherein the data processing apparatus is further configured to:
use the group identifier to associate the first multimedia object with the description about the group.

29. The system of claim 27, wherein the data processing apparatus is further configured to:
store a usage history in the memory unit, the usage history listing user actions and associating the first identifier with each user action that is related to the first multimedia object.

30. The system of claim 29, wherein the usage history includes a reference to a multimedia description.

31. The system of claim 27, wherein the data processing apparatus is further configured to:
use the first description or the description about the group to describe user preferences.

32. The system of claim 27, wherein the group of multimedia objects represents a series of episodes, and wherein the reference to the group indicates that the first multimedia object represents an episode of the series.

33. The system of claim 27, wherein the first description includes a hierarchical structure in which the reference to the group is represented at the same hierarchical level as a container including content description elements.

34. The system of claim 27, wherein the description about the group specifies a title, a genre, a director, or one or more actors or actresses for the group of multimedia objects.

35. A system for providing description of multimedia content, the system comprising:
data processing apparatus configured to generate a first description describing content in a first multimedia object, the first description including a first identifier and a reference to a group of multimedia objects, wherein the first identifier identifies the first multimedia object and the reference to the group indicates that the first multimedia object belongs to the group of multimedia objects; and
a transmitter configured to transmit the first description to a user terminal.

36. The system of claim 35, wherein the data processing apparatus is further configured to:
generate a description about the group of multimedia data objects, wherein the description about the group includes a title for the group of multimedia objects and a group identifier to identify the group of multimedia objects.

37. The system of claim 36, wherein the transmitter is further configured to:
transmit the description about the group to the user terminal.

38. The system of claim 35, wherein the reference to the group includes information to determine the group identifier.

39. The system of claim 35, wherein the group of multimedia objects represents a series of episodes, and wherein the reference to the group indicates that the first multimedia object is an episode of the series.

40. The system of claim 35, wherein the first description includes a hierarchical structure in which the reference to the group is represented at the same hierarchical-level as a container including content description elements.

41. The system of claim 40, wherein the content description elements in the first description include an element specifying a title, a genre, a director, an actor, or an actress for the first multimedia object.

42. A computer program product for processing description of multimedia content, the computer program comprising instructions to cause data processing apparatus to perform operations comprising:
receiving a first description describing content in a first multimedia object, the first description including a first identifier and a reference to a group of multimedia objects, wherein the first identifier identifies the first multimedia object and the reference to the group indicates that the first multimedia object belongs to the group of multimedia objects; and
receiving a description about the group of multimedia objects, wherein the description about the group includes a group identifier that identifies the group.

43. The product of claim 42, wherein the computer program further comprises instructions to cause data processing apparatus to perform operations comprising:
storing a usage history that lists user actions and associates the first identifier with each user action that is related to the first multimedia object.

44. The product of claim 42, wherein the group of multimedia objects represents a series of episodes, and wherein the reference to the group indicates that the first multimedia object represents an episode of the series.

45. The product of claim 42, wherein the first description includes a hierarchical structure in which the reference to the group is represented at the same hierarchical level as a container including content description elements.

46. A computer program product for providing description of multimedia content, the computer program comprising instructions to cause data processing apparatus to perform operations comprising:
generating a first description describing content in a first multimedia object, the first description including a first identifier and a reference to a group of multimedia objects, wherein the first identifier identifies the first multimedia object and the reference to the group indicates that the first multimedia object belongs to the group of multimedia objects; and
sending the first description to a user terminal.

47. The product of claim 46, wherein the computer program further comprises instructions to cause data processing apparatus to perform operations comprising:
generating a description about the group of multimedia data objects, wherein the description about the group includes a title for the group of multimedia objects and a group identifier to identify the group of multimedia objects.

48. The product of claim 46, wherein the group of multimedia objects represents a series of episodes, and wherein the reference to the group indicates that the first multimedia object is an episode of the series.

49. The product of claim 46, wherein the first description includes a hierarchical structure in which the reference to the group is represented at the same hierarchical level as a container including content description elements.

50. A system, comprising:
a user terminal; and
a server configured to:
generate a first description describing content in a first multimedia object, the first description including a first identifier and a reference to a group of multimedia objects, wherein the first identifier identifies the first multimedia object and the reference to the group indicates that the first multimedia object belongs to the group of multimedia objects; and
transmit the first description to the user terminal.

51. The system of claim 50, wherein the group of multimedia objects represents a series of episodes, and wherein the reference to the group indicates that the first multimedia object is an episode of the series.

52. The system of claim 50, wherein the server is further configured to:
generate a description about the group of multimedia objects, wherein the description about the group includes a title for the group of multimedia objects and a group identifier to identify the group of multimedia objects.
